(19) United States
(12) Patent Application Publication
(10) Pub. No.: US 2026/0212914 A1
(43) Pub. Date: Jul. 23, 2026

(54) MEMORY DEVICE INCLUDING BITLINE SENSE AMPLIFIER CIRCUIT

(71) Applicant: SAMSUNG ELECTRONICS CO., LTD., Suwon-si (KR)

(72) Inventors: Kangsub Jeong, Suwon-si (KR); Kyu-Chang Kang, Suwon-si (KR); Young Seok Park, Suwon-si (KR); Duckyoung Seo, Suwon-si (KR); Younghun Seo, Suwon-si (KR); Hoseok Lee, Suwon-si (KR)

(73) Assignee: SAMSUNG ELECTRONICS CO., LTD., Suwon-si (KR)

(21) Appl. No.: 19/447,616

(22) Filed: Jan. 13, 2026

(30) Foreign Application Priority Data
Jan. 23, 2025 (KR) 10-2025-0010314

(51) Int. Cl. G11C 11/4091; G11C 11/4094; G11C 11/4096

(52) U.S. Cl. CPC G11C 11/4091; G11C 11/4094; G11C 11/4096

(57) ABSTRACT

A memory device including: memory cells; bitlines connected to a portion of the memory cells; sense amplifiers respectively connected to the bitlines; and complementary bitlines connected to a second portion of the memory cells and respectively connected to the sense amplifiers. The sense amplifiers include first and second sense amplifiers. The bitlines include first and second bitlines adjacent to each other and respectively connected to the first and second sense amplifiers. The complementary bitlines include a first and second complementary bitlines connected to the first and second sense amplifiers. The first sense amplifier includes a first internal bitline. The first internal bitline connects to the first bitline during a sensing interval of a read operation. The second sense amplifier includes a second internal bitline adjacent to the first internal bitline. And, the second internal bitline connects to the second complementary bitline during the sensing interval.

### CROSS-REFERENCE TO RELATED APPLICATIONS

This application claims priority to Korean Patent Application No. 10-2025-0010314, filed on January 23, 2025, in the Korean Intellectual Property Office, the disclosure of which is incorporated by reference herein in its entirety.

### BACKGROUND

### 1. Field

The present disclosure relates to a semiconductor memory device, and more particularly, to a memory device including a bitline sense amplifier circuit.

### 2. Description of Related Art

A semiconductor memory may be mainly classified as a volatile memory or a non-volatile memory. Read and write speeds of the volatile memory (for example, a Dynamic Random Access Memory (DRAM) or a Static Random Access Memory (SRAM)) are fast, but the data stored in the volatile memory disappear when power is turned off. By contrast, non-volatile memory may retain data even when the power is turned off.

A representative example of a volatile memory device is a DRAM. A memory cell of a volatile memory device may include a single N-type transistor, serving as a switch, and a single capacitor storing electric charges DATA. Binary information (“1” or “0”) may correspond to the presence or absence of the electric charges stored in the capacitor in the memory cell, for example, whether a terminal voltage of a cell capacitor is high or low. The memory cell may be connected to a wordline and a bitline. The bitline may be connected to a sense amplifier. The sense amplifier may sense data, stored in the memory cell, through the bitline based on a voltage applied to the wordline.

Each of the memory cells of a volatile memory device may be connected to a bitline and a complementary bitline. In the volatile memory device, when a read operation or refresh operation is performed, the bitline sense amplifier may detect and amplify a voltage difference between the bitline and the complementary bitline. To improve integration density of the volatile memory device, various cell structures are being developed, and spacing between bitlines is decreasing. Accordingly, the probability of coupling occurring between the bitlines is increasing.

### SUMMARY

Provided is a bitline sense amplifier circuit normally performing a read operation regardless of parasitic capacitance occurring between bitlines, and a memory device including the same.

According to an aspect of the disclosure, a memory device includes: a memory cell array including a plurality of memory cells; a plurality of bitlines connected to a portion of the plurality of memory cells; a plurality of sense amplifiers respectively connected to the plurality of bitlines; and a plurality of complementary bitlines connected to a second portion of the plurality of memory cells and respectively connected to the plurality of sense amplifiers, wherein the plurality of sense amplifiers include a first sense amplifier and a second sense amplifier, wherein the plurality of bitlines include a first bitline and a second bitline which are adjacent to each other and which are respectively connected to the first sense amplifier and the second sense amplifier, wherein the plurality of complementary bitlines include a first complementary bitline connected to the first sense amplifier and a second complementary bitline connected to the second sense amplifier, wherein the first sense amplifier includes a first internal bitline, wherein the first internal bitline is configured to connect to the first bitline during a sensing interval of a read operation, wherein the second sense amplifier includes a second internal bitline adjacent to the first internal bitline, and wherein the second internal bitline is configured to connect to the second complementary bitline during the sensing interval.

According to an aspect of the disclosure, a memory device includes: a first memory cell; a second memory cell; a first bitline connected to the first memory cell; a second bitline adjacent to the first bitline and connected to the second memory cell; a first sense amplifier configured to sense a voltage level of the first bitline during a read operation; a second sense amplifier adjacent to the first sense amplifier and configured to sense a voltage level of the second bitline during the read operation; a first complementary bitline connected to the first sense amplifier and configured to have a voltage level complementary to the first bitline during a sensing interval of the read operation; and a second complementary bitline connected to the second sense amplifier and configured to have a voltage level complementary to the second bitline during the sensing interval, wherein the first sense amplifier includes a first sensing bitline, wherein the first sensing bitline is configured to connect to the first bitline during the sensing interval, wherein the second sense amplifier includes a second complementary sensing bitline, wherein the second complementary sensing bitline is configured to connect to the second complementary bitline during the sensing interval, and wherein the second complementary sensing bitline is adjacent to the first sensing bitline.

According to an aspect of the disclosure, a bitline sense amplifier circuit included in a memory device includes: a first sense amplifier connected to a first bitline and a first complementary bitline; and a second sense amplifier connected to a second bitline adjacent to the first bitline and a second complementary bitline adjacent to the first complementary bitline, wherein the first sense amplifier includes a first sensing bitline configured to connect to the first bitline during a sensing interval of a read operation of the memory device, wherein the second sense amplifier includes a second complementary sensing bitline connected to the second complementary bitline during the sensing interval, and wherein the second complementary sensing bitline is adjacent to the first sensing bitline.

### BRIEF DESCRIPTION OF DRAWINGS

The above and other aspects and features of the present disclosure will become apparent from the following description taken in conjunction with the accompanying drawings, in which:

FIG. 1 is a block diagram illustrating a memory system according to one or more embodiments;

FIG. 2 is a block diagram illustrating a memory device of FIG. 1;

FIG. 3 is a diagram illustrating a memory cell array and bitlines as referenced in FIG. 2 according to one or more embodiments;

FIG. 4 is a diagram illustrating a connection between the memory cell array and the bitline sense amplifier circuit of FIG. 2;

FIG. 5 is a diagram illustrating one of the sense amplifiers of FIG. 4 according to one or more embodiments;

FIG. 6 is a diagram illustrating a portion of the sense amplifiers and bitlines of FIG. 4;

FIG. 7 is a diagram illustrating a layout of bitlines connected to the first sense amplifier and the second sense amplifier of FIG. 6;

FIG. 8 is a circuit diagram of the first sense amplifier of FIG. 7;

FIG. 9 is a circuit diagram of the second sense amplifier of FIG. 7;

FIG. 10 is a timing diagram illustrating a read operation where a read error occurs due to the first parasitic capacitance occurring in the first bitline of FIG. 7; and

FIG. 11 is a timing diagram illustrating a read operation where the first parasitic capacitance occurring in the first bitline of FIG. 7 is offset.

### DETAILED DESCRIPTION

Below, one or more embodiments of the present disclosure will be described in detail and to such an extent that a person of ordinary one in the art may implement the present disclosure.

In the following description, like reference numerals refer to like elements throughout the specification. Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

Below, a DRAM will be used as an example for illustrating features and functions of the present disclosure. However, other features and performances may be understood from information disclosed herein by a person of ordinary skill in the art. The present disclosure may be implemented by other embodiments or applied thereto. Further, the detailed description may be modified or changed according to viewpoints and applications without escaping from the scope, spirit, and other objects of the present disclosure.

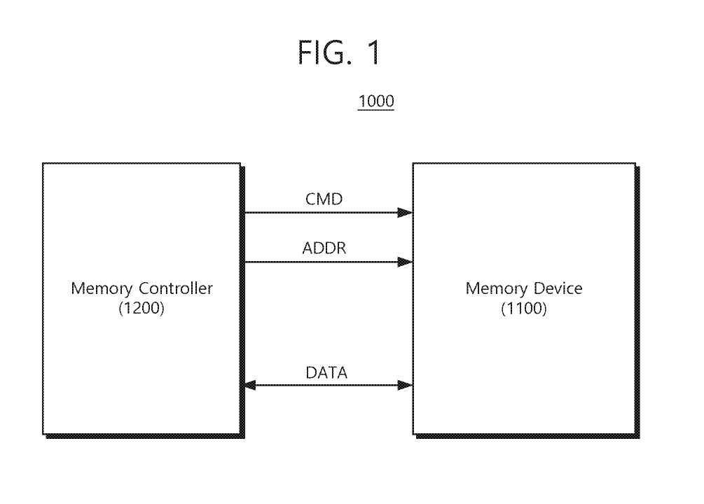

FIG. 1 is a block diagram illustrating a memory system according to one or more embodiments. Referring to FIG. 1, a memory system 1000 may include a memory device 1100 and a memory controller 1200.

The memory device 1100 may output data DATA, requested to be read by the memory controller 1200, to the memory controller 1200 or may store data DATA, requested to be written by the memory controller 1200, in one or more memory cells of the memory device 1100. The memory device 1100 may input and output data DATA based on the command CMD and the address ADDR. The memory device 1100 may include memory banks.

The memory device 1100 may be a volatile memory device such as a dynamic random access memory (DRAM), a synchronous dynamic random access memory (SDRAM), a double data rate (DDR) DRAM, a DDR SDRAM, a low-power double data rate (LPDDR) SDRAM, a graphics double data rate (GDDR) SDRAM, a Rambus dynamic random access memory (RDRAM), and a static random access memory (SRAM), or the like. Alternatively, the memory device 1100 may be implemented as a nonvolatile memory device such as a resistive RAM (RRAM), a phase change memory (PRAM), a magnetoresistive memory (MRAM), a ferroelectric memory (FRAM), a spin-transfer torque RAM (STT-RAM), or the like. While the present disclosure is described with respect to a DRAM, the present disclosure is not limited thereto.

The memory banks may include a memory cell array divided in units of banks, a row decoder, a column decoder, a sense amplifier, a write driver, or the like. The memory banks may store data DATA, requested to be written in the memory device 1100, through the write driver and may read data DATA, requested to be read, using the sense amplifier. The memory banks may further include a component for a refresh operation of storing and maintaining data in the cell array, or select circuits based on an address.

The memory controller 1200 may perform an access operation of writing data to the memory device 1100 or reading data stored in the memory device 1100. For example, the memory controller 1200 may generate a command CMD and an address ADDR for writing data to the memory device 1100 or reading data stored in the memory device 1100. The memory controller 1200 may include at least one of a control circuit controlling the memory device 1100, a system-on-chip (SoC) such as an application processor (AP), a central processing unit (CPU), a digital signal processor (DSP), and a graphics processing unit (GPU).

The memory controller 1200 may provide various signals to the memory device 1100 to control an overall operation of the memory device 1100. For example, the memory controller 1200 may control memory access operations of the memory device 1100 such as a read operation and a write operation. The memory controller 1200 may provide the command CMD and the address ADDR to the memory device 1100 to write data DATA in the memory device 1100 or to read data DATA from the memory device 1100.

The memory controller 1200 may generate various types of commands CMD to control the memory device 1100. For example, the memory controller 1200 may generate a bank request corresponding to a bank operation of changing a state of a memory bank, among memory banks, to read or write data DATA.

As an example, the bank request may include an activation request for changing a state of a memory bank, among the memory banks, to an active state. The memory device 1100 may activate a row included in the memory bank, for example, a wordline, in response to the activation request. The bank request may include a precharge request for changing the memory banks from an active state to a standby state after reading or writing of data DATA is completed.

In addition, the memory controller 1200 may generate an input/output (I/O) request (for example, a column address strobe (CAS) request) for the memory device 1100 to perform a read operation or a write operation of data DATA. As an example, the I/O request may include a read request for reading data DATA from activated memory banks. The I/O request may include a write request for writing data DATA in the activated memory banks.

Furthermore, the memory controller 1200 may generate a refresh command to control a refresh operation on the memory banks. However, the types of commands CMD described herein are merely exemplary, and other types of commands CMD may be present.

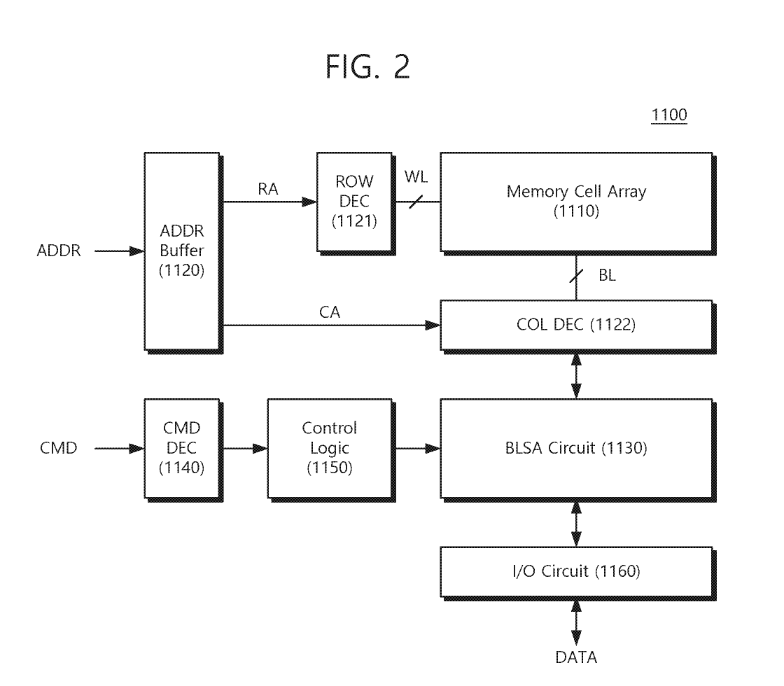

FIG. 2 is a block diagram illustrating a memory device of FIG. 1. Referring to FIG. 2, the memory device 1100 may include a memory cell array 1110, an address buffer 1120, a row decoder 1121, a column decoder 1122, a bitline sense amplifier 1130, a command decoder 1140, control logic 1150 and an input/output circuit 1160.

The memory cell array 1110 may include a plurality of memory cells arranged in a matrix of rows and columns. For example, the memory cell array 1110 may include a plurality of wordlines WL and a plurality of bitlines BL connected to memory cells. The plurality of wordlines WL may be connected to rows of the memory cells, and the plurality of bitlines BL may be connected to columns of the memory cells.

The address buffer 1120 may receive an address ADDR from the memory controller 1200 of FIG. 1. For example, the address ADDR may include a row address RA addressing a row of the memory cell array 1110 and a column address CA addressing a column of the memory cell array 1110. The address buffer 1120 may transmit the row address RA to the row decoder 1121 and may transmit the column address CA to the column decoder 1122.

The row decoder 1121 may select one of the plurality of wordlines WL connected to the memory cell array 1110. The row decoder 1121 may decode the row address RA, received from the address buffer 1120, to select a single wordline corresponding to the row address RA and may activate the selected wordline.

The column decoder 1122 may select a predetermined bitline from among the plurality of bitlines BL of the memory cell array 1110. The column decoder 1122 may decode the column address CA, received from the address buffer 1120, to select the predetermined bitline BL corresponding to the column address CA.

The bitline sense amplifier 1130 may be connected to the bitlines BL of the memory cell array 1110. For example, the bitline sense amplifier 1130 may sense a change in voltage of a selected bitline, among the plurality of bitlines BL, and may amplify and output the change in voltage.

The command decoder 1140 may decode a write enable signal /WE, a row address strobe signal /RAS, a column address strobe signal /CAS, and a chip select signal /CS received from the memory controller 1200 such that control signals corresponding to the command CMD are generated in the control logic 1150. The command CMD may include an activation request, a read request, a write request, or a precharge request.

The control logic 1150 may control an overall operation of the bitline sense amplifier 1130 through the control signals corresponding to the command CMD. The control logic 1150 may generate control signals such that the bitline sense amplifier 1130 operates as a single-ended sense amplifier. Additionally, the control logic 1150 may control an overall operation of the memory device 1100.

The input/output circuit 1160 may output data DATA to the memory controller 1200 through data pad based on a sensed and amplified voltage from the bitline sense amplifier 1130. For example, the input/output circuit 1160 may include an input buffer or an output buffer. The input buffer or the output buffer may be connected to the data pad. The input/output circuit 1160 may perform a serialization operation or a deserialization operation of data DATA.

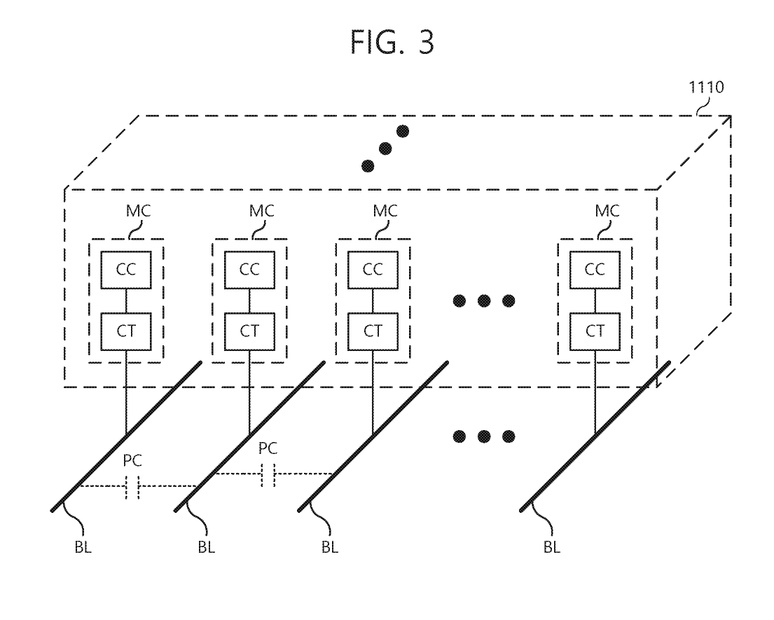

FIG. 3 is a diagram illustrating a memory cell array and bitlines as referenced in FIG. 2 according to one or more embodiments. Referring to FIG. 3, the memory cell array 1110 may include a plurality of memory cells MC.

One memory cell MC may include a cell transistor CT and a cell capacitor CC. One end of the cell transistor CT may be connected to a bitline BL. The other end of the cell transistor CT may be connected to the cell capacitor CC. A gate of the cell transistor CT may be connected to a wordline WL of FIG. 2.

In one memory cell MC, the cell transistor CT and the cell capacitor CC may be formed to be stacked in one direction with respect to the bitline BL. Accordingly, integration density of the plurality of memory cells MC in a certain area may increase. However, spacing between bitlines BL decreases, and parasitic capacitance PC may occur between adjacent bitlines BL.

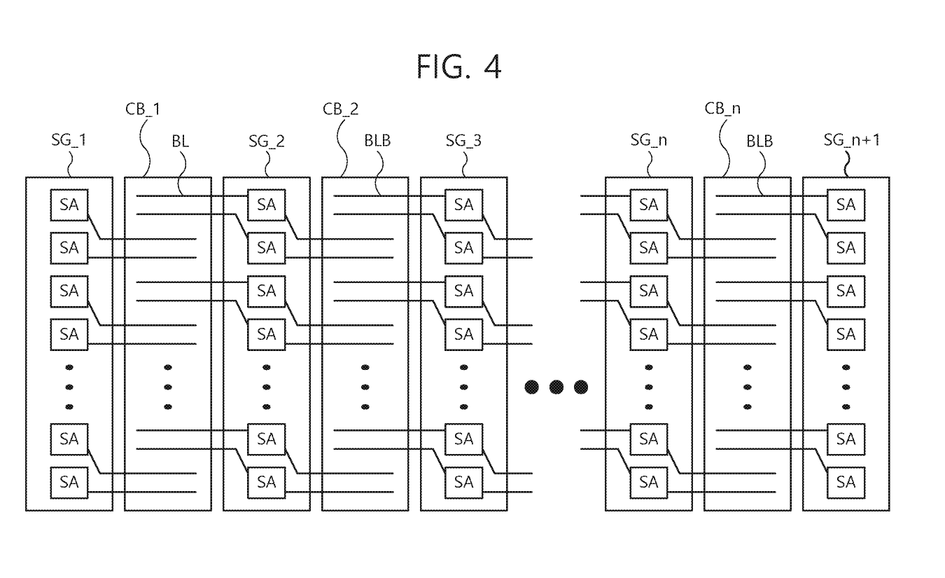

FIG. 4 is a diagram illustrating a connection between the memory cell array and the bitline sense amplifier circuit of FIG. 2. Referring to FIGS. 2 and 4, the memory cell array 1110 may include a plurality of memory cell blocks CB_1 to CB_n. Each of the plurality of memory cell blocks CB_1 to CB_n may include the plurality of memory cells MC of FIG. 3.

The bitline sense amplifier circuit 1130 may include a plurality of sense amplifier blocks SG_1 to SG_n+1. Each of the plurality of sense amplifier blocks SG_1 to SG_n+1 may include a plurality of sense amplifiers SA.

A portion (for example, CB_1) of the plurality of memory cell blocks CB_1 to CB_n may be connected to a plurality of bitlines BL extending in one direction (for example, the column direction). Each of the plurality of bitlines BL may be connected to the plurality of memory cells MC. Each of the plurality of memory cell blocks CB_1 to CB_n may be connected to a plurality of wordlines WL extending in a different direction (for example, the row direction). The plurality of memory cells MC connected to each bitline may be connected to the plurality of wordlines WL to form a grid array.

A portion (for example, CB_2) of the plurality of memory cell blocks CB_1 to CB_n may be connected to a plurality of complementary bitlines BLB. Memory cell blocks connected to the bitlines BL and/or memory cell blocks connected to the complementary bitlines BLB may be arranged alternately. As an example, a first memory cell block CB_1 may be connected to a plurality of bitlines BL. A second memory cell block CB_2 may be connected to a plurality of complementary bitlines BLB.

A portion (for example, SG_1 and/or SG_n) of the plurality of sense amplifier blocks SG_1 to SG_n+1 may be connected to only one of either bitlines BL or complementary bitlines BLB. As an example, sense amplifiers SA included in a first sense amplifier block SG_1 may be connected only to bitlines BL. Sense amplifiers SA included in a (n+1)th sense amplifier block SG_n+1 may be connected only to complementary bitlines BLB.

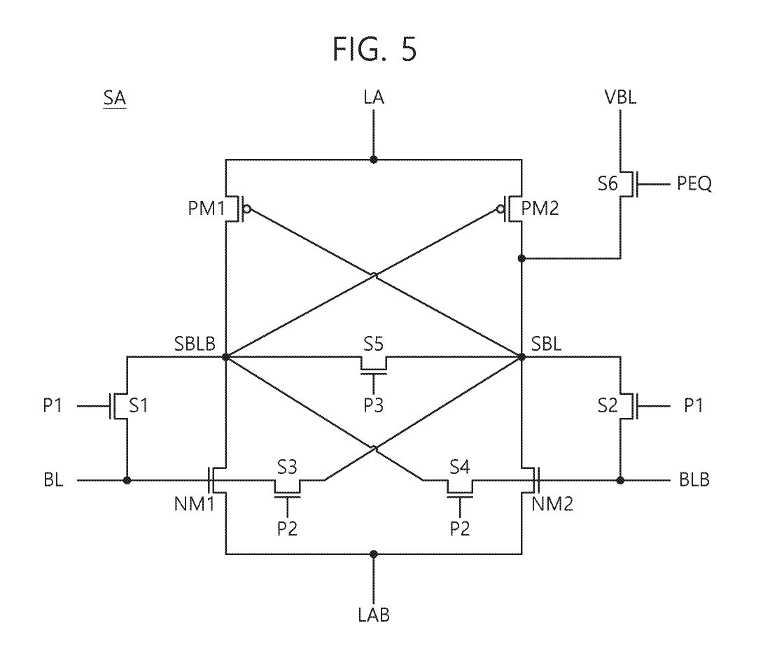

FIG. 5 is a diagram illustrating one of the sense amplifiers of FIG. 4 according to one or more embodiments. Referring to FIG. 5, one sense amplifier SA may include an N-type sense amplifier and a P-type sense amplifier. For example, the N-type sense amplifier may be composed of N-type transistors (for example, a first N-type transistor NM1 and a second N-type transistor NM2). The P-type sense amplifier may be composed of P-type transistors (for example, a first P-type transistor PM1 and a second P-type transistor PM2).

One sense amplifier SA may include a plurality of switching transistors. For example, a first switching transistor S1 may be connected between a bitline BL and a complementary sensing bitline SBLB. The first switching transistor S1 may connect or disconnect the bitline BL and the complementary sensing bitline SBLB based on a first switching signal P1. A second switching transistor S2 may be connected between a complementary bitline BLB and a sensing bitline SBL. The second switching transistor S2 may connect or disconnect the complementary bitline BLB and the sensing bitline SBL based on the first switching signal P1.

A third switching transistor S3 may be connected between the bitline BL and the sensing bitline SBL. The third switching transistor S3 may connect or disconnect the bitline BL and the sensing bitline SBL based on a second switching signal P2. A fourth switching transistor S4 may be connected between the complementary bitline BLB and the complementary sensing bitline SBLB. The fourth switching transistor S4 may connect or disconnect the complementary bitline BLB and the complementary sensing bitline SBLB based on the second switching signal P2.

A fifth switching transistor S5 may be connected between the sensing bitline SBL and the complementary sensing bitline SBLB. The fifth switching transistor S5 may connect or disconnect the sensing bitline SBL and the complementary sensing bitline SBLB based on a third switching signal P3.

A sixth switching transistor S6 may be connected between a line of a precharge voltage VBL and the sensing bitline SBL. The sixth switching transistor S6 may connect or disconnect the line of the precharge voltage VBL and the sensing bitline SBL based on an equalization signal PEQ.

The N-type sense amplifier and the P-type sense amplifier may be connected between the sensing bitline SBL and the complementary sensing bitline SBLB. The N-type sense amplifier and the P-type sense amplifier may detect and amplify a voltage difference between the bitline BL and the complementary bitline BLB based on voltages of a control line LA and a complementary control line LAB.

For example, one end of the first P-type transistor PM1 may be connected to the control line LA, the other end of the first P-type transistor PM1 may be connected to the complementary sensing bitline SBLB, and the gate of the first P-type transistor PM1 may be connected to the sensing bitline SBL. One end of the second P-type transistor PM2 may be connected to the control line LA, the other end of the second P-type transistor PM2 may be connected to the sensing bitline SBL, and the gate of the second P-type transistor PM2 may be connected to the complementary sensing bitline SBLB.

One end of the first N-type transistor NM1 may be connected to the complementary sensing bitline SBLB, the other end of the first N-type transistor NM1 may be connected to the complementary control line LAB, and the gate of the first N-type transistor NM1 may be connected to the bitline BL. One end of the second N-type transistor NM2 may be connected to the sensing bitline SBL, the other end of the second N-type transistor NM2 may be connected to the complementary control line LAB, and the gate of the second N-type transistor NM2 may be connected to the complementary bitline BLB.

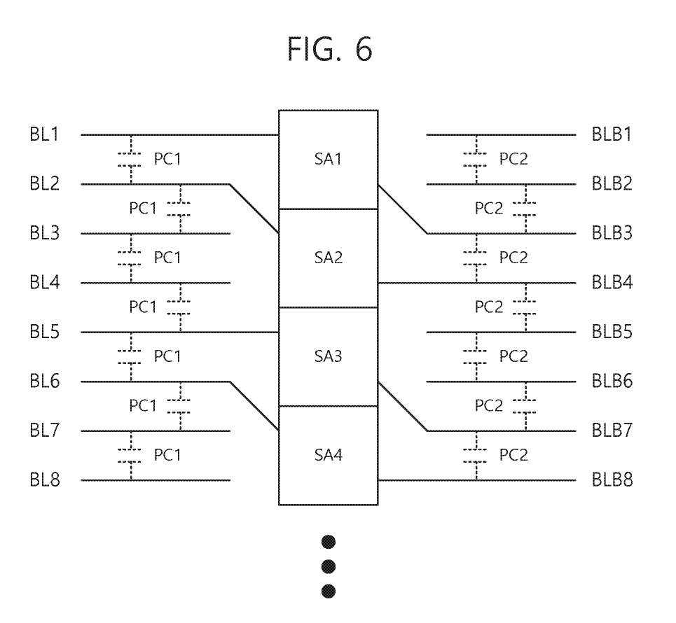

FIG. 6 is a diagram illustrating a portion of the sense amplifiers and bitlines of FIG. 4. Referring to FIG. 6, one sense amplifier may be connected to one bitline and one complementary bitline. The bitline and the complementary bitline may be included in different memory cell blocks of FIG. 3. The bitlines are arranged parallel to each other, and parasitic capacitance may occur due to coupling between adjacent bitlines during a read operation.

Each of a plurality of bitlines BL1 to BL8 may be respectively connected to one sense amplifier. For example, bitlines BL1, BL2, BL5, BL6 may be connected to sense amplifiers SA1, SA2, SA3, SA4, respectively, which are included in one sense amplifier group. Bitlines BL3, BL4, BL7, BL8 may be connected to sense amplifiers included in another sense amplifier group, respectively. As an example, the first bitline BL1 may be connected to the first sense amplifier SA1. The second bitline BL2 may be connected to the second sense amplifier SA2.

Each of a plurality of complementary bitlines BLB1 to BLB8 may be respectively connected to one sense amplifier. For example, complementary bitlines BLB3, BLB4, BLB7, BLB8 may be connected to sense amplifiers SA1, SA2, SA3, SA4, respectively, which are included in one sense amplifier group. Complementary bitlines BLB1, BLB2, BLB5, BLB6 may be connected to sense amplifiers included in another sense amplifier group, respectively. As an example, the third complementary bitline BLB3 may be connected to the first sense amplifier SA1. The fourth complementary bitline BLB4 may be connected to the second sense amplifier SA2.

A first parasitic capacitance PC1 may occur between the first bitline BL1 and the second bitline BL2. A second parasitic capacitance PC2 may occur between the third complementary bitline BLB3 and the fourth complementary bitline BLB4. As an example, the first parasitic capacitance PC1 may be the same as the second parasitic capacitance PC2. As another example, the first parasitic capacitance PC1 may be different from the second parasitic capacitance PC2.

Two adjacent bitlines (for example, BL1, BL2) may be connected to sense amplifiers included in the same sense amplifier group. Or two adjacent bitlines (for example, BL2, BL3) may be connected to sense amplifiers included in different sense amplifier groups.

Two adjacent complementary bitlines (for example, BLB3, BLB4) may be connected to sense amplifiers included in the same sense amplifier group. Or two adjacent complementary bitlines (for example, BLB2, BLB3) may be connected to sense amplifiers included in different sense amplifier groups.

However, the foregoing description is exemplary, and the connection relationship between sense amplifiers and bitlines (or sense amplifiers and complementary bitlines) may be variously changed.

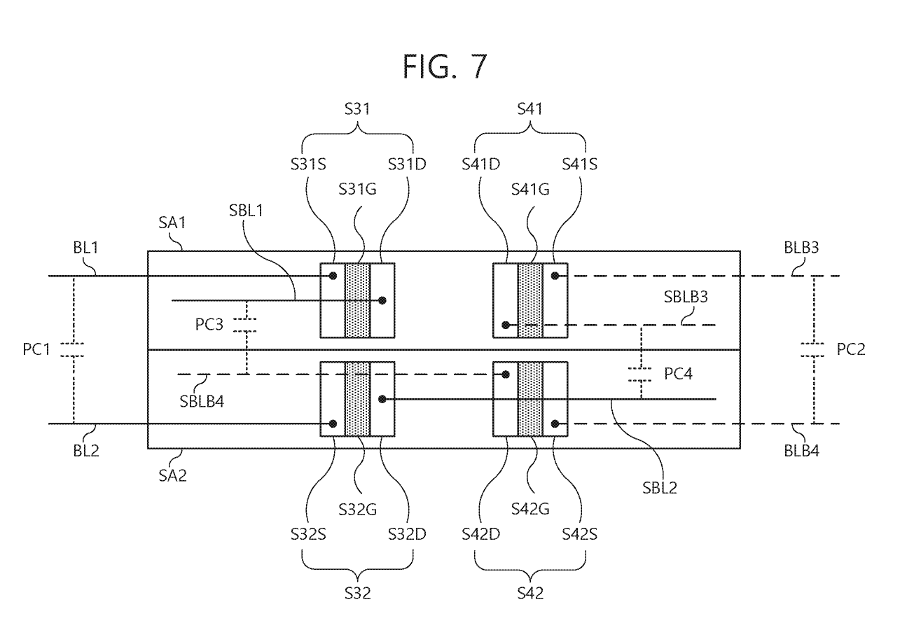

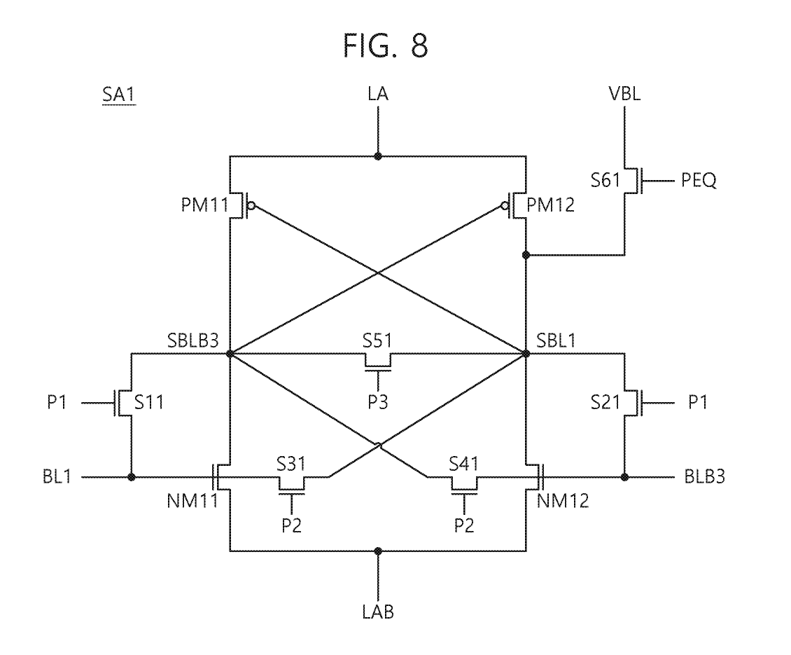

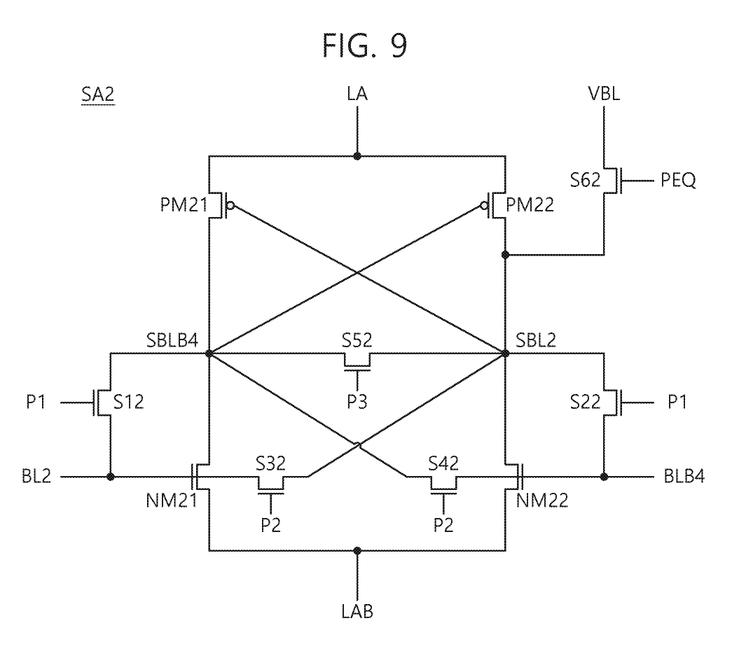

FIG. 7 is a diagram illustrating a layout of bitlines connected to the first sense amplifier and the second sense amplifier of FIG. 6. FIG. 8 is a circuit diagram of the first sense amplifier of FIG. 7. FIG. 9 is a circuit diagram of the second sense amplifier of FIG. 7. Referring to FIGS. 7 and 8, the first sense amplifier SA1 may be connected to the first bitline BL1 and the third complementary bitline BLB3. Referring to FIGS. 7 and 9, the second sense amplifier SA2 may be connected to the second bitline BL2 and the fourth complementary bitline BLB4.

Referring to FIGS. 7 and 8, the first sense amplifier SA1 may include a plurality of switching transistors. For example, an eleventh switching transistor S11 may connect or disconnect the first bitline BL1 and a third complementary sensing bitline SBLB3 based on a first switching signal P1. A twenty-first switching transistor S21 may connect or disconnect the third complementary bitline BLB3 and a first sensing bitline SBL1 based on the first switching signal P1.

A thirty-first switching transistor S31 may connect or disconnect the first bitline BL1 and the first sensing bitline SBL1 based on a second switching signal P2. A forty-first switching transistor S41 may connect or disconnect the third complementary bitline BLB3 and the third complementary sensing bitline SBLB3 based on the second switching signal P2.

A fifty-first switching transistor S51 may connect or disconnect the first sensing bitline SBL1 and the third complementary sensing bitline SBLB3 based on a third switching signal P3. A sixty-first switching transistor S61 may connect or disconnect a line of a precharge voltage VBL and the first sensing bitline SBL1 based on an equalization signal PEQ.

One end of an eleventh P-type transistor PM11 may be connected to a control line LA, the other end of the eleventh P-type transistor PM11 may be connected to the third complementary sensing bitline SBLB3, and a gate of the eleventh P-type transistor PM11 may be connected to the first sensing bitline SBL1. One end of a twelfth P-type transistor PM12 may be connected to the control line LA, the other end of the twelfth P-type transistor PM12 may be connected to the first sensing bitline SBL1, and a gate of the twelfth P-type transistor PM12 may be connected to the third complementary sensing bitline SBLB3.

One end of an eleventh N-type transistor NM11 may be connected to the third complementary sensing bitline SBLB3, the other end of the eleventh N-type transistor NM11 may be connected to a complementary control line LAB, and a gate of the eleventh N-type transistor NM11 may be connected to the first bitline BL1. One end of a twelfth N-type transistor NM12 may be connected to the first sensing bitline SBL1, the other end of the twelfth N-type transistor NM12 may be connected to the complementary control line LAB, and a gate of the twelfth N-type transistor NM12 may be connected to the third complementary bitline BLB3.

Referring to FIGS. 7 and 9, the second sense amplifier SA2 may include a plurality of switching transistors. For example, a twelfth switching transistor S12 may connect or disconnect the second bitline BL2 and a fourth complementary sensing bitline SBLB4 based on the first switching signal P1. A twenty-second switching transistor S22 may connect or disconnect the fourth complementary bitline BLB4 and a second sensing bitline SBL2 based on the first switching signal P1.

A thirty-second switching transistor S32 may connect or disconnect the second bitline BL2 and the second sensing bitline SBL2 based on the second switching signal P2. A forty-second switching transistor S42 may connect or disconnect the fourth complementary bitline BLB4 and the fourth complementary sensing bitline SBLB4 based on the second switching signal P2.

A fifty-second switching transistor S52 may connect or disconnect the second sensing bitline SBL2 and the fourth complementary sensing bitline SBLB4 based on the third switching signal P3. A sixty-second switching transistor S62 may connect or disconnect the line of the precharge voltage VBL and the second sensing bitline SBL2 based on the equalization signal PEQ.

One end of a twenty-first P-type transistor PM21 may be connected to the control line LA, the other end of the twenty-first P-type transistor PM21 may be connected to the fourth complementary sensing bitline SBLB4, and a gate of the twenty-first P-type transistor PM21 may be connected to the second sensing bitline SBL2. One end of a twenty-second P-type transistor PM22 may be connected to the control line LA, the other end of the twenty-second P-type transistor PM22 may be connected to the second sensing bitline SBL2, and a gate of the twenty-second P-type transistor PM22 may be connected to the fourth complementary sensing bitline SBLB4.

One end of a twenty-first N-type transistor NM21 may be connected to the fourth complementary sensing bitline SBLB4, the other end of the twenty-first N-type transistor NM21 may be connected to the complementary control line LAB, and a gate of the twenty-first N-type transistor NM21 may be connected to the second bitline BL2. One end of a twenty-second N-type transistor NM22 may be connected to the second sensing bitline SBL2, the other end of the twenty-second N-type transistor NM22 may be connected to the complementary control line LAB, and a gate of the twenty-second N-type transistor NM22 may be connected to the fourth complementary bitline BLB4.

Referring to FIGS. 7 to 9, the first sense amplifier SA1 may include the thirty-first switching transistor S31 connecting the first bitline BL1 and the first sensing bitline SBL1. The first sense amplifier SA1 may include the forty-first switching transistor S41 connecting the third complementary bitline BLB3 and the third complementary sensing bitline SBLB3.

The thirty-first switching transistor S31 may include a source S31S, a gate S31G and a drain S31D. The source S31S may be connected to the first bitline BL1. The drain S31D may be connected to the first sensing bitline SBL1. The second switching signal P2 may be input to the gate S31G.

The forty-first switching transistor S41 may include a source S41S, a gate S41G and a drain S41D. The source S41S may be connected to the third complementary bitline BLB3. The drain S41D may be connected to the third complementary sensing bitline SBLB3. The second switching signal P2 may be input to the gate S41G.

The second sense amplifier SA2 may include the thirty-second switching transistor S32 connecting between the second bitline BL2 and the second sensing bitline SBL2. The second sense amplifier SA2 may include the forty-second switching transistor S42 connecting between the fourth complementary bitline BLB4 and the fourth complementary sensing bitline SBLB4.

The thirty-second switching transistor S32 may include a source S32S, a gate S32G and a drain S32D. The source S32S may be connected to the second bitline BL2. The drain S32D may be connected to the second sensing bitline SBL2. The second switching signal P2 may be input to the gate S31G.

The forty-second switching transistor S42 may include a source S42S, a gate S42G and a drain S42D. The source S42S may be connected to the fourth complementary bitline BLB4. The drain S42D may be connected to the fourth complementary sensing bitline SBLB4. The second switching signal P2 may be input to the gate S42G.

The first parasitic capacitance PC1 may occur between the first bitline BL1 and the second bitline BL2. The second parasitic capacitance PC2 may occur between the third complementary bitline BLB3 and the fourth complementary bitline BLB4.

The first sensing bitline SBL1 (for example, a first internal bitline) of the first sense amplifier SA1 may be adjacent to the fourth complementary sensing bitline SBLB4 (for example, a second internal bitline) of the second sense amplifier SA2. Accordingly, a third parasitic capacitance PC3 may occur between the first sensing bitline SBL1 and the fourth complementary sensing bitline SBLB4.

The third complementary sensing bitline SBLB3 (for example, a third internal bitline) of the first sense amplifier SA1 may be adjacent to the second sensing bitline SBL2 (for example, a fourth internal bitline) of the second sense amplifier SA2. Accordingly, a fourth parasitic capacitance PC4 may occur between the third complementary sensing bitline SBLB3 and the second sensing bitline SBL2.

As an example, the third parasitic capacitance PC3 may be set to be the same as the fourth parasitic capacitance PC4. As another example, the third parasitic capacitance PC3 may be set to be different from the fourth parasitic capacitance PC4.

During a read operation, the first parasitic capacitance PC1 may be offset by the third parasitic capacitance PC3. Also, the second parasitic capacitance PC2 may be offset by the fourth parasitic capacitance PC4.

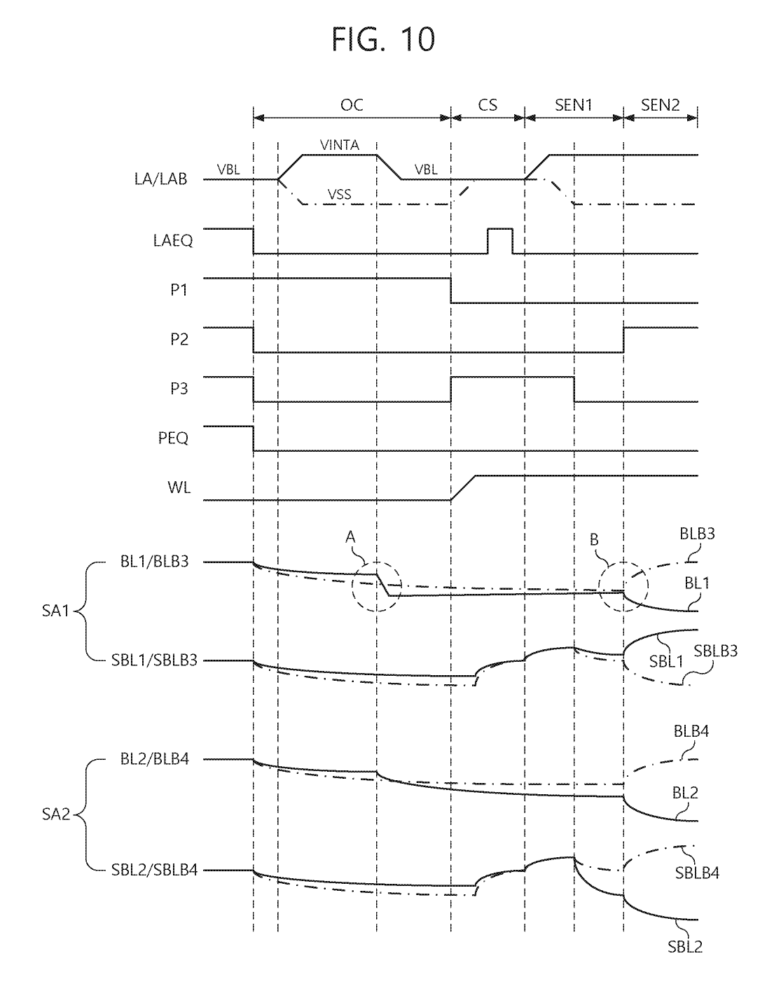

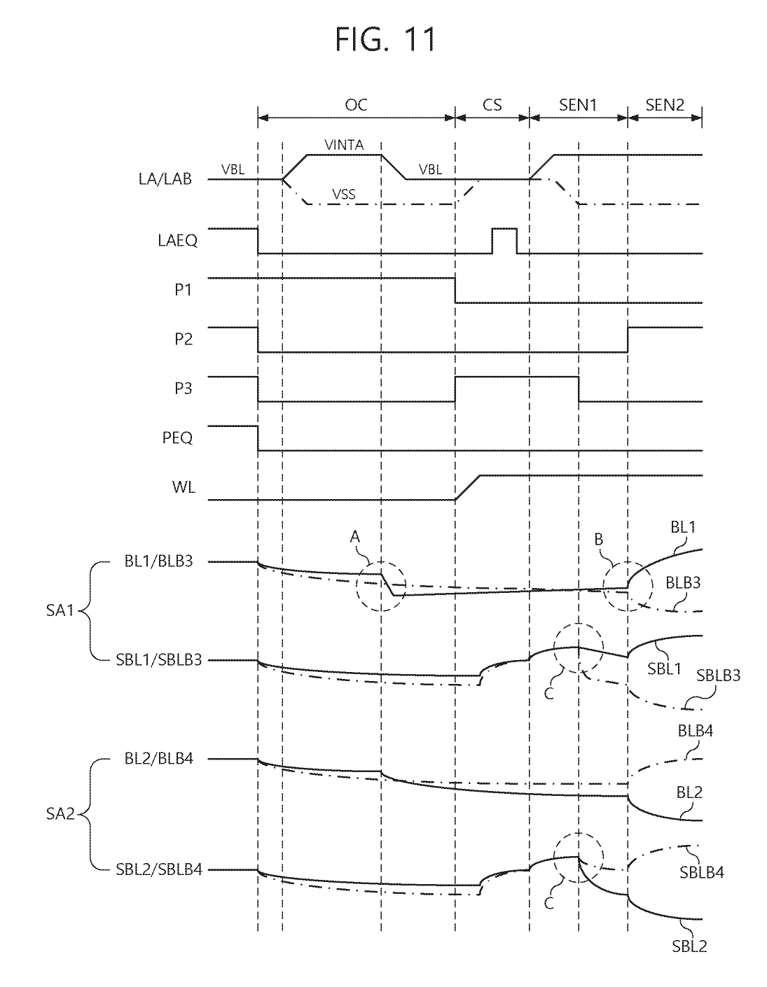

FIG. 10 is a timing diagram illustrating a read operation where a read error occurs due to the first parasitic capacitance occurring in the first bitline of FIG. 7. FIG. 11 is a timing diagram illustrating a read operation where the first parasitic capacitance occurring in the first bitline of FIG. 7 is offset. FIG. 10 illustrates a read operation in case the arrangement of sensing bitlines and complementary sensing bitlines described in FIGS. 6 and 7 is not applied. FIG. 11 illustrates a read operation where an arrangement of sensing bitlines and complementary sensing bitlines described in FIGS. 6 and 7 is applied.

Referring to FIGS. 10 and 11, the first parasitic capacitance PC1 may occur at time point A. Referring to FIG. 10, a read error due to the first parasitic capacitance PC1 may occur at time point B. Referring to FIG. 11, the third parasitic capacitance PC3 due to the arrangement of sensing bitlines and complementary sensing bitlines described in FIGS. 6 and 7 may occur at time point C. In FIGS. 10 and 11, it is exemplarily explained that a memory cell connected to the first bitline BL1 stores data of a high level (logic 1), a memory cell connected to the second bitline BL2 stores data of a low level (logic 0), and the first sense amplifier SA1 reads the memory cell connected to the first bitline BL1.

Before an offset compensation interval OC, the first sense amplifier SA1 and the second sense amplifier SA2 may perform a precharge operation. For example, bitlines BL1 and BL2, complementary bitlines BLB3 and BLB4, sensing bitlines SBL1 and SBL2, and complementary sensing bitlines SBLB2 and SBLB4 may be equalized to the precharge voltage VBL. The first switching signal P1, the second switching signal P2, the third switching signal P3, the equalization signal PEQ and a control line equalization signal LAEQ may have a high level.

During the offset compensation interval OC, the equalization signal PEQ and the control line equalization signal LAEQ may be changed to a low level. At this time, a first internal voltage VINTA higher than the precharge voltage VBL may be applied to the control line LA, and a second internal voltage VSS lower than the precharge voltage VBL may be applied to the complementary control line LAB.

The second switching signal P2 and the third switching signal P3 may be changed to a low level, and the first switching signal P1 may be maintained at a high level. Accordingly, the bitlines BL1 and BL2 may be separated from the sensing bitlines SBL1 and SBL2. The complementary bitlines BLB3 and BLB4 may be separated from the complementary sensing bitlines SBLB2 and SBLB4. During the offset compensation interval OC, offsets of the P-type transistors P11, P12, P21, P22 and the N-type transistors N11, N12, N21, N22 may be compensated.

Until time point A, voltage levels of the bitlines BL1 and BL2, the complementary bitlines BLB3 and BLB4, the sensing bitlines SBL1 and SBL2, and the complementary sensing bitlines SBLB2 and SBLB4 may gradually decrease from the precharge voltage VBL due to the P-type transistors P11, P12, P21, P22 and the N-type transistors N11, N12, N21, N22.

At time point A, a voltage level of the control line LA may be changed from the first internal voltage VINTA to the precharge voltage VBL. At this time, coupling occurs between the bitlines BL1 and BL2, and the voltage level of the first bitline BL1 may rapidly decrease based on the first parasitic capacitance PC1 and the voltage level of the second bitline BL2.

In FIG. 10, when a decrease of a voltage level due to coupling based on the first parasitic capacitance PC1 is not compensated, a voltage level of the first bitline BL1 may not recover during the charge sharing interval CS and the first sensing interval SEN1. Accordingly, at time point B, the voltage level of the first bitline BL1 may become lower than a voltage level of the third complementary bitline BLB3. Therefore, although a memory cell connected to the first bitline BL1 stores data of a high level (logic 1), the first sense amplifier SA1 may incorrectly recognize the data of the first bitline BL1 as a low level (logic 0) in the second sensing interval SEN2.

In FIG. 11, during the charge sharing interval CS, the control line equalization signal LAEQ may be temporarily changed to a high level, and the control line LA and the complementary control line LAB may be reset to the precharge voltage VBL. A low level may be applied to the first switching signal P1 and the second switching signal P2. A high level may be applied to the third switching signal P3. Accordingly, voltage levels of the sensing bitlines SBL1 and SBL2, and the complementary sensing bitlines SBLB2 and SBLB4 may be changed to the precharge voltage VBL. At this time, a wordline WL may be changed to a high level, and each of the bitlines BL1 and BL2, and the complementary bitlines BLB3 and BLB4 may perform charge sharing with a cell capacitor of a connected memory cell.

In the first sensing interval SEN1, the control line LA may be changed to the first internal voltage VINTA, and the complementary control line LAB may be changed again to the second internal voltage VSS. Accordingly, voltage levels of sensing bitlines SBL1 and SBL2, and complementary sensing bitlines SBLB2 and SBLB4 may rise additionally.

Also, at time point C, the third parasitic capacitance PC3 may occur between the first sensing bitline SBL1 and the fourth complementary sensing bitline SBLB4. The fourth parasitic capacitance PC4 may occur between the third complementary sensing bitline SBLB3 and the second sensing bitline SBL2. Accordingly, a voltage level of the first sensing bitline SBL1 may decrease less than in the case of FIG. 10. A voltage level of the third complementary sensing bitline SBLB3 may decrease more than in the case of FIG. 10.

In the second sensing interval SEN2, the third switching signal P3 may be changed to a low level, and the second switching signal P2 may be changed to a high level. Due to the third parasitic capacitance PC3, the first sensing bitline SBL1 of the first sense amplifier SA1 may maintain a voltage level similar to the fourth complementary sensing bitline SBLB4 of the second sense amplifier SA2. By the second switching signal P2, the first bitline BL1 may be connected to the first sensing bitline SBL1, the second bitline BL2 may be connected to the second sensing bitline SBL2, and a voltage level of the first bitline BL1, which had been decreased due to the first parasitic capacitance PC1, may become higher than the voltage level of the third complementary bitline BLB3 again at time point B. Therefore, the first sense amplifier SA1 may accurately recognize the data of the first bitline BL1 as a high level (logic 1).

As described above, the voltage level of the first bitline BL1 may be changed to an abnormal range due to the first parasitic capacitance PC1 resulting from coupling with the second bitline BL2. However, through the third parasitic capacitance PC3 due to the arrangement of sensing bitlines and complementary sensing bitlines described in FIGS. 6 and 7, the voltage level of the first bitline BL1 may be changed back to a normal range during the read operation. Accordingly, the first sense amplifier SA1 may accurately sense the data of the memory cell connected to the first bitline BL1 regardless of coupling with the second bitline BL2. Also, the first sense amplifier SA1 may accurately sense the data of the memory cell connected to the first bitline BL1 without a shield structure between the first bitline BL1 and the second bitline BL2.

At least one of the components, elements, modules, units, or the like (collectively "components" in this paragraph) represented by a block or an equivalent indication (collectively “block”) in the above embodiments including the drawings such as FIGS. 1 and 2, for example, the address buffer, row decoder, column decoder, command decoder, control logic, and input/output circuit, controller, counter circuit, flip-flop, latch, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

According to the present disclosure, it may be possible to normally perform a read operation even when parasitic capacitance occurs between bitlines without a shield structure to block the parasitic capacitance between the bitlines in the bitline sense amplifier circuit included in the memory device.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array comprising a plurality of memory cells;
a plurality of bitlines connected to a portion of the plurality of memory cells;
a plurality of sense amplifiers respectively connected to the plurality of bitlines; and
a plurality of complementary bitlines connected to a second portion of the plurality of memory cells and respectively connected to the plurality of sense amplifiers,
wherein the plurality of sense amplifiers comprise a first sense amplifier and a second sense amplifier,
wherein the plurality of bitlines comprise a first bitline and a second bitline which are adjacent to each other and which are respectively connected to the first sense amplifier and the second sense amplifier,
wherein the plurality of complementary bitlines comprise a first complementary bitline connected to the first sense amplifier and a second complementary bitline connected to the second sense amplifier,
wherein the first sense amplifier comprises a first internal bitline,
wherein the first internal bitline is configured to connect to the first bitline during a sensing interval of a read operation,
wherein the second sense amplifier comprises a second internal bitline adjacent to the first internal bitline, and
wherein the second internal bitline is configured to connect to the second complementary bitline during the sensing interval.

2. The memory device of claim 1, wherein a first parasitic capacitance between the first bitline and the second bitline is offset by a second parasitic capacitance between the first internal bitline and the second internal bitline during the sensing interval.

3. The memory device of claim 2, wherein the first sense amplifier comprises a third internal bitline configured to connect to the first complementary bitline during the sensing interval,
wherein the second sense amplifier comprises a fourth internal bitline adjacent to the third internal bitline and configured to connect to the second bitline during the sensing interval, and
wherein a third parasitic capacitance between the first complementary bitline and the second complementary bitline is offset by a fourth parasitic capacitance between the third internal bitline and the fourth internal bitline.

4. The memory device of claim 3, wherein the third parasitic capacitance is the same as the first parasitic capacitance.

5. The memory device of claim 3, wherein the fourth parasitic capacitance is the same as the second parasitic capacitance.

6. The memory device of claim 1, wherein each of the plurality of memory cells comprise a cell transistor and a cell capacitor,
wherein the cell transistor is on each of the plurality of bitlines, and
wherein the cell capacitor is on the cell transistor.

7. A memory device comprising:
a first memory cell;
a second memory cell;
a first bitline connected to the first memory cell;
a second bitline adjacent to the first bitline and connected to the second memory cell;
a first sense amplifier configured to sense a voltage level of the first bitline during a read operation;
a second sense amplifier adjacent to the first sense amplifier and configured to sense a voltage level of the second bitline during the read operation;
a first complementary bitline connected to the first sense amplifier and configured to have a voltage level complementary to the first bitline during a sensing interval of the read operation; and
a second complementary bitline connected to the second sense amplifier and configured to have a voltage level complementary to the second bitline during the sensing interval,
wherein the first sense amplifier comprises a first sensing bitline,
wherein the first sensing bitline is configured to connect to the first bitline during the sensing interval,
wherein the second sense amplifier comprises a second complementary sensing bitline,
wherein the second complementary sensing bitline is configured to connect to the second complementary bitline during the sensing interval, and
wherein the second complementary sensing bitline is adjacent to the first sensing bitline.

8. The memory device of claim 7, wherein the first sense amplifier comprises:
a first P-type transistor connected between a control line and a first complementary sensing bitline, the first P-type transistor comprising a gate connected to the first sensing bitline;
a second P-type transistor connected between the control line and the first sensing bitline, the second P-type transistor comprising a gate connected to the first complementary sensing bitline;
a first N-type transistor connected between a complementary control line and the first complementary sensing bitline, the first N-type transistor comprising a gate connected to the first bitline; and
a second N-type transistor connected between the complementary control line and the first sensing bitline, the second N-type transistor comprising a gate connected to the first complementary bitline, and
wherein the second sense amplifier comprises:
a third P-type transistor connected between the control line and the second complementary sensing bitline, the third P-type transistor comprising a gate connected to a second sensing bitline;
a fourth P-type transistor connected between the control line and the second sensing bitline, the fourth P-type transistor comprising a gate connected to the second complementary sensing bitline;
a third N-type transistor connected between the complementary control line and the second complementary sensing bitline, the third N-type transistor comprising a gate connected to the second bitline; and
a fourth N-type transistor connected between the complementary control line and the second sensing bitline, the fourth N-type transistor comprising a gate connected to the second complementary bitline.

9. The memory device of claim 8, wherein a first parasitic capacitance between the first bitline and the second bitline is offset by a second parasitic capacitance between the first sensing bitline and the second complementary sensing bitline.

10. The memory device of claim 9, wherein the first parasitic capacitance occurs during an offset compensation interval of the read operation while the first bitline is connected to the first complementary sensing bitline and the second bitline is connected to the second complementary sensing bitline.

11. The memory device of claim 9, wherein the second parasitic capacitance occurs during the sensing interval while the first sensing bitline is connected to the first complementary sensing bitline and the second sensing bitline is connected to the second complementary sensing bitline.

12. The memory device of claim 9, wherein a third parasitic capacitance between the first complementary bitline and the second complementary bitline is offset by a fourth parasitic capacitance between the first complementary sensing bitline and the second sensing bitline.

13. The memory device of claim 12, wherein the third parasitic capacitance is the same as the first parasitic capacitance.

14. The memory device of claim 12, wherein the fourth parasitic capacitance is the same as the second parasitic capacitance.

15. A bitline sense amplifier circuit included in a memory device, the bitline sense amplifier circuit comprising:
a first sense amplifier connected to a first bitline and a first complementary bitline; and
a second sense amplifier connected to a second bitline adjacent to the first bitline and a second complementary bitline adjacent to the first complementary bitline,
wherein the first sense amplifier comprises a first sensing bitline configured to connect to the first bitline during a sensing interval of a read operation of the memory device,
wherein the second sense amplifier comprises a second complementary sensing bitline connected to the second complementary bitline during the sensing interval, and
wherein the second complementary sensing bitline is adjacent to the first sensing bitline.

16. The bitline sense amplifier circuit of claim 15, wherein the first sense amplifier further comprises:
a first P-type transistor connected between a control line and a first complementary sensing bitline, the first P-type transistor comprising a gate connected to the first sensing bitline;
a second P-type transistor connected between the control line and the first sensing bitline, the second P-type transistor comprising a gate connected to the first complementary sensing bitline;
a first N-type transistor connected between a complementary control line and the first complementary sensing bitline, the first N-type transistor comprising a gate connected to the first bitline; and
a second N-type transistor connected between the complementary control line and the first sensing bitline, the second N-type transistor comprising a gate connected to the first complementary bitline, and
wherein the second sense amplifier further comprises:
a third P-type transistor connected between the control line and the second complementary sensing bitline, the third P-type transistor comprising a gate connected to a second sensing bitline;
a fourth P-type transistor connected between the control line and the second sensing bitline, the fourth P-type transistor comprising a gate connected to the second complementary sensing bitline;
a third N-type transistor connected between the complementary control line and the second complementary sensing bitline, the third N-type transistor comprising a gate connected to the second bitline; and
a fourth N-type transistor connected between the complementary control line and the second sensing bitline, the fourth N-type transistor comprising a gate connected to the second complementary bitline.

17. The bitline sense amplifier circuit of claim 16, wherein the first sense amplifier further comprises a first switching transistor comprising a source connected to the first bitline, a drain connected to the first sensing bitline, and a gate configured to receive a switching signal is applied,
wherein the second sense amplifier further comprises a second switching transistor including a source connected to the second complementary bitline, a drain connected to the second complementary sensing bitline, and a gate configured to receive the switching signal is applied, and
wherein the first sensing bitline and the second complementary sensing bitline are adjacent and parallel to each other.

18. The bitline sense amplifier circuit of claim 16, wherein a first parasitic capacitance between the first bitline and the second bitline is offset by a second parasitic capacitance between the first sensing bitline and the second complementary sensing bitline.

19. The bitline sense amplifier circuit of claim 18, wherein a third parasitic capacitance between the first complementary bitline and the second complementary bitline is offset by a fourth parasitic capacitance between the first complementary sensing bitline and the second sensing bitline.

20. The bitline sense amplifier circuit of claim 19, wherein the third parasitic capacitance the same as the first parasitic capacitance, and
wherein the fourth parasitic capacitance is the same as the second parasitic capacitance.
